(19) United States
(12) Patent Application Publication
(10) Pub. No.: US 2021/0405417 A1
(43) Pub. Date: Dec. 30, 2021

(54) Display Device and Method for Manufacturing Display Device

(71) Applicants: BEIJING BOE DISPLAY TECHNOLOGY CO., LTD., Beijing (CN); BOE Technology Group Co., Ltd., Beijing (CN)

(72) Inventors: Jingjing JIANG, Beijing (CN); Xiaona LIU, Beijing (CN); Mengjie WANG, Beijing (CN); Yu MA, Beijing (CN); Weitao CHEN, Beijing (CN); Jiabin ZOU, Beijing (CN); Yujia SUN, Beijing (CN)

(21) Appl. No.: 17/336,343

(22) Filed: Jun. 2, 2021

(30) Foreign Application Priority Data
Jun. 30, 2020 (CN) 202010619340.8

(51) Int. Cl. G02F 1/1339; G02F 1/1335; G03F 7/00

(52) U.S. Cl. CPC G02F 1/13394; G03F 7/0007; G02F 1/133512; G02F 1/13396

(57) ABSTRACT

Provided are a display device and a manufacturing method thereof, wherein the display device includes a display substrate and an opposite substrate which are oppositely arranged cell-assembled, and a first spacer disposed between the display substrate and the opposite substrate; a cross-section of the first spacer has a shape of rounded polygon.

### CROSS-REFERENCE TO RELATED APPLICATION

The present application claims the priority of Chinese Patent Application No. 202010619340.8 filed to the CNIPA on Jun. 30, 2020, the content of which is hereby incorporated by reference.

### TECHNICAL FIELD

Embodiments of the present disclosure relate to, but are not limited to, the field of display technology, in particular to a display device and a method for manufacturing the display device.

### BACKGROUND

Liquid Crystal Display (LCD) has the advantages such as small size, low power consumption and no radiation. It has developed rapidly in recent years and made great progress in both screen size and display quality. Currently, the development of LCD focuses on improving picture quality and reducing production cost.

### SUMMARY

The following is a summary of subject matters described in detail in the present disclosure. This summary is not intended to limit the protection scope of the claims.

In a first aspect, the present disclosure provides a display device, including a display substrate and an opposite substrate which are oppositely disposed and cell-assembled, and a first spacer disposed between the display substrate and the opposite substrate;

a cross-section of the first spacer has a shape of rounded polygon.

In some possible implementations, the cross-section of the first spacer has a shape of rounded rectangle.

In some possible implementations, the display device further includes a second spacer is provided between the display substrate and the opposite substrate;

a cross-section of the second spacer has the same shape as the cross-section of the first spacer, and the first spacer has a height greater than a height of the second spacer.

In some possible implementations, the display device further includes: a plurality of sub-pixel regions arranged in an array and a third spacer disposed between the display substrate and the opposite substrate,

the third spacer is located in the plurality of sub-pixel regions.

In some possible implementations, the third spacer is located in two or three sub-pixel regions.

In some possible implementations, the third spacer includes M sub-spacers and (M-1) connection parts; and

each sub-spacer is located in one of the sub-pixel regions, and two adjacent sub-spacers are connected by one of the connection parts, the sub-spacer has a height equal to a height of the second spacer, and the connection part has a height equal to the height of the sub-spacer.

In some possible implementations, a cross-section of the sub-spacer has a shape of circle, ellipse or rounded polygon, and a cross-section of the connection part has a shape of strip.

In some possible implementations, a surface of the connection part close to the display substrate has a width smaller than a width of a surface of the sub-spacer close to the display substrate.

In some possible implementations, the surface of the connection part close to the display substrate has a width greater than or equal to 6 microns.

In some possible implementations, the display substrate or the opposite substrate includes a black matrix layer provided with a plurality of openings, and each sub-pixel region comprises a black matrix region and an opening region, and the black matrix region surrounds the opening region;

each of the first spacer, the second spacer and the third spacer includes: a first surface close to the display substrate and a second surface close to the opposite substrate, wherein the first surface has an area larger than an area of the second surface;

a minimum distance between an edge of a first surface of the first spacer and an edge of a black matrix region in a sub-pixel region where the first spacer is located is greater than 12 microns.

In some possible implementations, a minimum distance between an edge of a first surface of the second spacer and an edge of a black matrix region in a sub-pixel region where the second spacer is located is greater than 10 microns; and

In some possible implementations, a minimum distance between an edge of a first surface of any sub-spacer in the third spacer and an edge of a black matrix region in a sub-pixel region where the sub-spacer is located is greater than 10 microns.

In some possible implementations, the first spacer includes: a first surface close to the display substrate and a second surface close to the opposite substrate, wherein the first surface has an area larger than an area of the second surface;

a sum of the areas of first surfaces of all first spacers in a unit area is larger than a first threshold area, wherein the unit area is 1 square millimeter.

In some possible implementations, the first spacer and the second spacer include: each of the first spacer and the second spacer includes a first surface close to the display substrate and a second surface close to the opposite substrate, wherein the first surface has an area larger than an area of the second surface;

a sum of the areas of first surfaces of all first spacers in a unit area is larger than a first threshold area, and a sum of the areas of first surfaces of all first spacers and first surfaces of all second spacers in a unit area is larger than a second threshold area, wherein the unit area is 1 square millimeter.

In some possible implementations, the display device is divided into multiple pixel blocks arranged periodically, and each pixel block includes M*N sub-pixel regions; and each pixel block is provided with a first spacer, a second spacer and a third spacer;

the pixel block has a length of 2 microns to 3 microns, and the pixel block has a width of 2 microns to 3 microns; and
the first spacer, the second spacer and the third spacer in each pixel block are evenly arranged in a same way.

In some possible implementations, each of the first spacer, the second spacer and the third spacer includes: a first surface close to the display substrate and a second surface close to the opposite substrate, wherein the first surface has an area larger than an area of the second surface;

in each pixel block, a sum of the areas of first surfaces of all first spacers in a unit area is larger than a first threshold area, and a sum of the areas of first surfaces of all first spacers, first surfaces of all second spacers, and first surfaces of all third spacers in a unit area is larger than a second threshold area, wherein the unit area is 1 square millimeter.

In some possible implementations, each first spacer is located in a sub-pixel region, and each second spacer is located in a sub-pixel region,

in each pixel block, a sub-pixel region adjacent to the sub-pixel region where the first spacer is located is provided with a second spacer, and a blank sub-pixel region is spaced from the sub-pixel region where the first spacer is located by one or two sub-pixel regions.

In a second aspect, the present disclosure also provides a method for manufacturing a display device, for manufacturing the above display device, and the method includes:

forming a display substrate and an opposite substrate which are cell-assembled;

forming a first spacer on the display substrate or the opposite substrate, wherein a cross-section of the first spacer has a shape of rounded polygon,

the forming the first spacer on the display substrate or the opposite substrate includes: coating a spacer film on the display substrate or the opposite substrate, performing exposure processing on the spacer film through a mask, and developing the spacer film on which exposure processing is performed to form a first spacer,

the mask includes a non-light transmittance region and a light transmittance region; the light transmittance region is polygonal, and multiple corners of the light transmittance region are provided with exposure compensation patterns, and

the performing exposure processing on the spacer film through the mask includes: performing exposure processing on the spacer film through the light transmittance region of the mask, and performing exposure compensation on the spacer film through the plurality of corners of the light transmittance region of the mask.

In some possible implementations, the forming the first spacer on the display substrate or the opposite substrate includes:

forming the first spacer and the second spacer, or the first spacer, the second spacer and the third spacer on the display substrate or the opposite substrate.

In some possible implementations, the light transmittance region is rectangular.

Other aspects will become apparent upon reading and understanding accompanying drawings and the detailed description.

### BRIEF DESCRIPTION OF DRAWINGS

Accompanying drawings are used to provide an understanding of technical solutions of the present disclosure and form a part of the specification. Together with embodiments of the present disclosure, they are used to explain the technical solutions of the present disclosure and do not constitute a limitation on the technical solutions of the present disclosure.

FIG. 1 is a schematic diagram of a structure of a display device according to an embodiment of the present disclosure.

FIG. 2 is a cross-sectional view of a first spacer according to an exemplary embodiment.

FIG. 3 is a schematic diagram of a structure of a display device according to an exemplary embodiment.

FIG. 4 is a cross-sectional view of a display device according to an exemplary embodiment.

FIG. 5 is a top view of a display device according to an exemplary embodiment.

FIG. 6 is a top view of a third spacer according to an exemplary embodiment.

FIG. 7 is a schematic diagram of a structure of a sub-pixel where a first spacer or a second spacer is located.

FIG. 8 is a schematic diagram of a structure of a sub-pixel where a third spacer is located.

FIG. 9 is a schematic diagram of a structure of a display device according to an exemplary embodiment.

FIG. 10A is a first top view of a mask according to an exemplary embodiment.

FIG. 10B is a second top view of a mask according to an exemplary embodiment.

FIG. 10C is a third top view of a mask according to an exemplary embodiment.

FIG. 10D is a fourth top view of a mask according to an exemplary embodiment.

FIG. 10E is a fifth top view of a mask according to an exemplary embodiment.

### DETAILED DESCRIPTION

Multiple embodiments are described in the present disclosure, but the description is exemplary rather than restrictive, and for those of ordinary skills in the art, there may be more embodiments and implementation solutions within the scope of the embodiments described in the present disclosure. Although many possible combinations of features are shown in the drawings and discussed in the Detailed Description, many other combinations of the disclosed features are also possible. Unless specifically limited, any feature or element of any embodiment may be used in combination with or in place of any other feature or element of any other embodiment.

The present disclosure includes and contemplates combinations of features and elements known to those of ordinary skilled in the art. The disclosed embodiments, features and elements of the present disclosure may be combined with any regular features or elements to form a technical solution defined by the claims. Any feature or element of any embodiment may also be combined with features or elements from another technical solution to form another technical solution defined by the claims. Therefore, it should be understood that any of the features shown and discussed in the present disclosure may be implemented individually or in any suitable combination. Therefore, the embodiments are not otherwise limited except in accordance with the appended claims and equivalents thereof. In addition, various modifications and changes may be made within the protection scope of the appended claims.

Unless otherwise defined, technical terms or scientific terms used in the present disclosure shall have ordinary meanings understood by those of ordinary skills in the art to which the present disclosure belongs. The words “first”, “second” and the like used in the present disclosure do not indicate any order, quantity or importance, but are only used to distinguish different components. Similar words such as “including” or “containing” mean that elements or articles appearing before the word cover elements or articles listed after the word and their equivalents, without excluding other elements or articles. Similar words such as “connect” or “link” are not limited to physical or mechanical connections, but may include electrical connections, whether direct or indirect. “Up”, “down”, “left”, “right”, etc. are only used to represent a relative position relationship that may change accordingly when an absolute position of an object being described changes.

In the present disclosure, “about” means that there is no strict limit for a value, and values within a range of process and measurement errors are allowable.

A liquid crystal display device includes a color filter substrate and an array substrate, and a liquid crystal layer composed of liquid crystal materials is disposed between these two substrates. In order to control the stability of the thickness of the liquid crystal layer, spacers are disposed between the color filter substrate and the array substrate to support the array substrate and the color filter substrate. For some low-resolution liquid crystal displays, the support area of spacers is usually insufficient, which weakens the resistance to pressure of the liquid crystal displays.

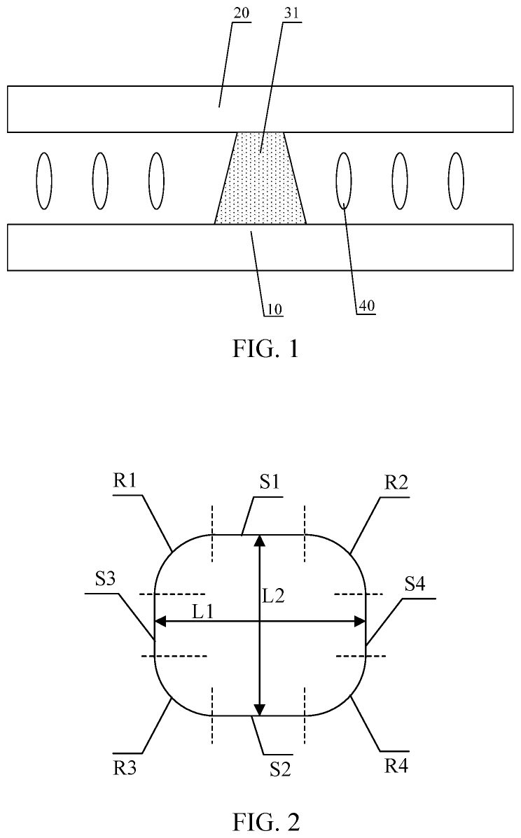

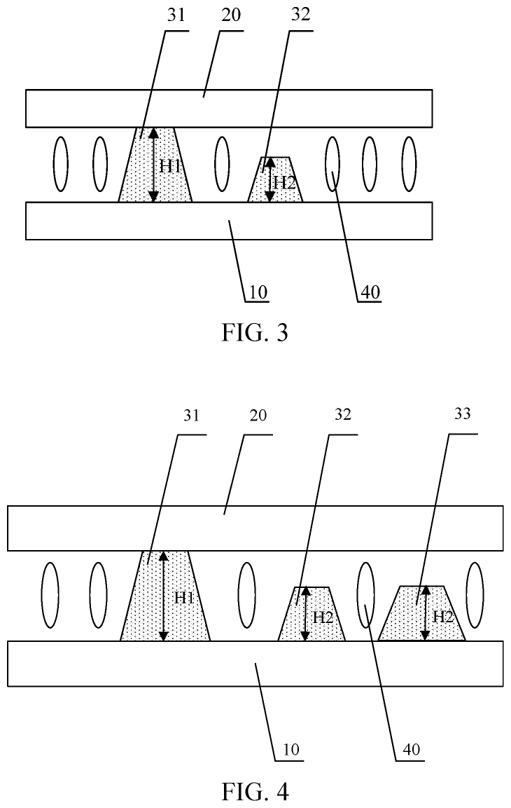

FIG. 1 is a schematic diagram of a structure of a display device according to an embodiment of the present disclosure, and FIG. 2 is a cross-sectional view of a first spacer according to an exemplary embodiment. As shown in FIG. 1 and FIG. 2, a display device provided by an embodiment of the present disclosure may include: a display substrate 10 and an opposite substrate 20 which are oppositely disposed and cell-assembled, and a first spacer 31 disposed between the display substrate 10 and the opposite substrate 20. A cross-section of the first spacer 31 may have a shape of a rounded polygon.

In an exemplary embodiment, a rounded polygon may be a rounded rectangle or a rounded hexagon etc., which is not limited by the embodiments of the present disclosure. For example, FIG. 2 illustrates an example in which the rounded polygon is the rounded rectangle. In an exemplary embodiment, a cross-section refers to a cross section on a plane parallel to the display substrate.

In an exemplary embodiment, a first spacer may be disposed at a regular position that is not parallel to a long side and a short side of a display panel, and may be rotated slightly, for example, at an angle.

As shown in FIG. 1, a display device provided by an exemplary embodiment may further include a liquid crystal layer 40, which is disposed between a display substrate 10 and an opposite substrate 20. For example, the liquid crystal layer 40 may include liquid crystal molecules, and the liquid crystal molecules are deflected by an electric field.

In an exemplary embodiment, a first spacer may be disposed to support the display substrate and the opposite substrate when the display device is not pressed.

In an exemplary embodiment, the display substrate may be an array substrate, and the opposite substrate may be a color filter substrate; or, the display substrate may be a color filter substrate, and the opposite substrate may be an array substrate, which is not limited by the embodiments of the present disclosure.

In an exemplary embodiment, the array substrate may include: gate lines, data lines, thin film transistors, and pixel electrodes electrically connected to the thin film transistors.

In an exemplary embodiment, the color filter substrate may include: a black matrix, a color filter layer and a protection layer.

In an exemplary embodiment, a display device may further include a common electrode, which may be disposed on the array substrate or on the color filter substrate.

In an exemplary embodiment, the black matrix may have a thickness of 1.1 microns to 1.4 microns.

In an exemplary embodiment, the thickness of the color filter layer may have a thickness 1 microns to 3 microns.

In an exemplary embodiment, the thickness of the protection layer may have a thickness of 1.6 microns to 1.8 microns.

In an exemplary embodiment, the first spacer may be fixed on the array substrate, or may be fixed on the color filter substrate, which is not limited by the embodiments of the present disclosure.

In an exemplary embodiment, a cross-section of the first spacer along an arrangement direction of the display substrate and the opposite substrate may be rectangle, regular trapezoid or inverted trapezoid.

In an exemplary embodiment, the display device may be any product or component with a display function such as a mobile phone, a tablet computer, a TV set, a display, a notebook computer, a digital photo frame, a navigator, etc. Those of ordinary skill in the art understand that the display device has other essential components, which will not be described in detail here, and should not be taken as a limitation of the present disclosure.

A display device provided by an embodiment of the disclosure includes a display substrate and an opposite substrate which are oppositely disposed and a first spacer disposed between the display substrate and the opposite substrate; a cross-section of the first spacer has a shape of rounded polygon. The present disclosure increases the contact area of the first spacer by providing the first spacer whose cross-section has the shape of rounded polygon, thus improving the resistance to pressure of the display device.

In an exemplary embodiment, as shown in FIG. 2, a rounded rectangle may include a first straight part S1, a second straight part S2, a third straight part S3, a fourth straight part S4, a first curved part R1, a second curved part R2, a third curved part R3 and a fourth curved part R4.

In an exemplary embodiment, the first straight part S1 and the second straight part S2 are disposed in parallel, and the first straight part S1 has a length equal to a length of the second straight part S2. The third straight part S3 and the fourth straight part S4 are disposed in parallel, and the third straight part S3 has a length equal to a length of the fourth straight part S4. The extending directions of the first straight part S1 and the third straight part S3 are perpendicular to each other, and the length of the third straight part S3 is smaller than or equal to the length of the first straight part S1.

In an exemplary embodiment, one end of the first curved part R1 is connected to one end of the first straight part S1, the other end of the first curved part R1 is connected to one end of the third straight part S3, and the first straight part S1 and the third straight part S3 are tangent to the first curved part R1. One end of the second curved part R2 is connected to the other end of the first straight part S1, the other end of the second curved part R2 is connected to one end of the fourth straight part S4, and the first straight part S1 and the fourth straight part S4 are tangent to the second curved part R2. One end of the third curved part R3 is connected to the other end of the third straight part S3, the other end of the third curved part R3 is connected to one end of the second straight part S2, and the second straight part S2 and the third straight part S3 are tangent to the third curved part R3. One end of the fourth curved part R4 is connected to the other end of the first straight part S1, the other end of the fourth curved part R4 is connected to the other end of the fourth straight part S4, and the first straight part S1 and the fourth straight part S4 are tangent to the fourth curved part R4.

In an exemplary embodiment, the first spacer may include a first surface close to the display substrate and a second surface close to the opposite substrate. The shapes of a first surface and a second surface may be a rounded polygon.

As shown in FIG. 2, a length of the first surface along a first direction is a first length L1, and a length of the first surface along a second direction is a second length L2, wherein the first direction is an extending direction of the first straight part and the second direction is an extending direction of the third straight part.

In an exemplary embodiment, the first length L1 may be greater than the second length L2, or may be equal to the second length L2.

In an exemplary embodiment, the first length L1 may be about 15 to 17 microns, for example, the first length may be 16 microns.

In an exemplary embodiment, the second length L2 may be about 13 microns to 15 microns, for example, the second length may be 14 microns.

In an exemplary embodiment, material for manufacturing the first spacer may include: photoresist, or other photosensitive material.

FIG. 3 is a schematic diagram of a structure of a display device according to an exemplary embodiment. As shown in FIG. 3, a display device in an exemplary embodiment may further include a second spacer 32 disposed between a display substrate 10 and an opposite substrate 20.

In an exemplary embodiment, a cross-section of the second spacer 32 may have the same shape as the cross-section of a first spacer 31. The first spacer 31 may have a heigh L1 greater than a height H2 of the second spacer 32. The height of the first spacer refers to a length of the first spacer along an arrangement direction of the display substrate and the opposite substrate, and the height of the second spacer refers to a length of the second spacer along the arrangement direction of the display substrate and the opposite substrate.

In an exemplary embodiment, the second spacer 32 may be disposed to support the display substrate and the opposite substrate when the display device is pressed. The disposition of the second spacer may prevent the liquid crystal layer from being damaged and improve the display effect of the display device.

In an exemplary embodiment, a surface of the second spacer 32 close to the display substrate may have an area smaller than or equal to an area of the first spacer 31 close to the display substrate, which is not limited by the present disclosure.

In an exemplary embodiment, material for manufacturing the second spacer 32 may include: photoresist, or other photosensitive material.

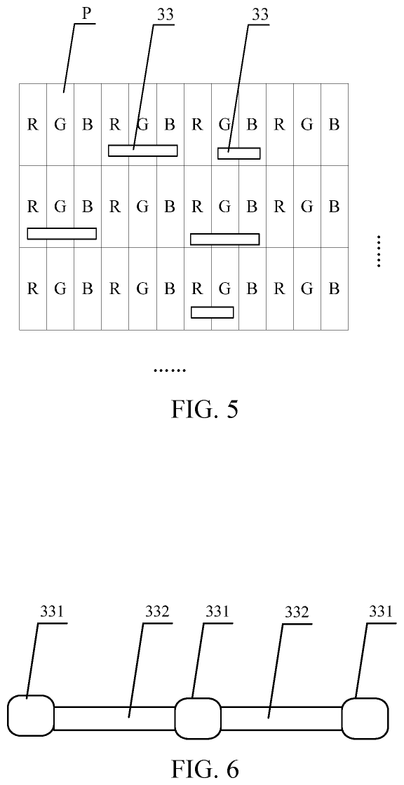

FIG. 4 is a cross-sectional view of a display device according to an exemplary embodiment, FIG. 5 is a top view of a display device according to an exemplary embodiment, And FIG. 6 is a top view of a third spacer according to an exemplary embodiment. As shown in FIG. 4 to FIG. 6, a display device provided by an exemplary embodiment further includes a plurality of sub-pixel regions P arranged in an array and a third spacer 33 disposed between a display substrate and an opposite substrate. The third spacer 33 is located in the plurality of sub-pixel regions.

In an exemplary embodiment, material for manufacturing the third spacer 33 may include: photoresist, or other photosensitive material.

In an exemplary embodiment, the sub-pixel regions may be red, green, or blue sub-pixel regions.

In an exemplary embodiment, the third spacer 33 may be located in two or three sub-pixel regions. FIG. 5 illustrates an example in which some third spacers are located in two sub-pixel regions and some third spacers are located in three sub-pixels.

In an exemplary embodiment, the first spacer and the second spacer may be located in one sub-pixel region.

In an exemplary embodiment, as shown in FIG. 6, the third spacer 33 includes M sub-spacers 331 and (M-1) connection parts 332. Each sub-spacer 331 is located in a one of the sub-pixel regions, and two adjacent sub-spacers are connected by one of the connection parts 332. FIG. 6 illustrates an example in which a third spacer 33 includes three sub-spacers and two connection parts.

In an exemplary embodiment, the sub-spacer 331 may have a height equal to a height of the second spacer.

In an exemplary embodiment, the connection part 332 may have a height equal to the height of the sub-spacer.

In an exemplary embodiment, M may equal to 2 or 3. The disposition of the third spacer may prevent the third spacer from blocking the liquid crystal molecules in the liquid crystal layer and prevent the liquid crystal molecules from diffusing.

In an exemplary embodiment, a cross-section of the sub-spacer 331 may have a shape of circle, ellipse, or rounded polygon. FIG. 6 illustrates an example in which the cross-section of the sub-spacer has a shape of rounded polygon.

In an exemplary embodiment, the cross-section of the connection part 332 may have a shape of strip.

In an exemplary embodiment, a surface of the connection part 332 close to a display substrate may have a width smaller than a width of a surface of the sub-spacer close to the display substrate, which may reduce the flow resistance of liquid crystal molecules and improve the display effect of the display device.

In an exemplary embodiment, the surface of the connection part 332 close to the display substrate may have a width greater than or equal to 6 microns, for example, 8 microns. According to an exemplary embodiment, the width of the surface of the connection part 332 close to the display substrate may ensure that the connection part 332 plays its supporting role.

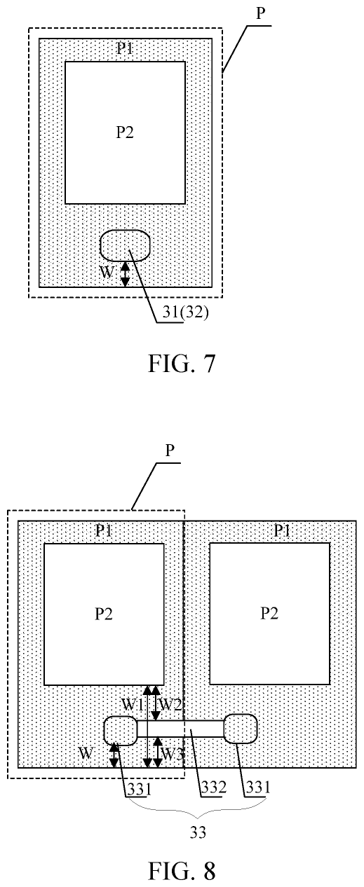

In an exemplary embodiment, FIG. 7 is a schematic diagram of structure of a sub-pixel where a first spacer or a second spacer is located, and FIG. 8 is a schematic diagram of structure of a sub-pixel where a third spacer is located. As shown in FIG. 7 and FIG. 8, in a display device according to an exemplary embodiment, a display substrate or an opposite substrate may include: a black matrix layer provided with a plurality of openings, and each sub-pixel region includes a black matrix region P1 and an opening region P2, wherein the black matrix region P1 surrounds the opening region P2.

In an exemplary embodiment, each of the first spacer, the second spacer, and the third spacer may include a first surface close to the display substrate and a second surface close to the opposite substrate, wherein, the first surface has an area larger than an area of the second surface.

In an exemplary embodiment, a minimum distance W between an edge of a first surface of the first spacer 31 and an edge of a black matrix region in a sub-pixel region where the first spacer is located may be greater than 12 microns. According to an exemplary embodiment, the minimum distance between the edge of the first surface of the first spacer 31 and the edge of the black matrix region in the sub-pixel region where the first spacer is located may ensure the display effect of the display device.

In an exemplary embodiment, a minimum distance W between an edge of a first surface of the second spacer 32 and an edge of a black matrix region in a sub-pixel region where the second spacer is located may be greater than 10 microns. According to an exemplary embodiment, the minimum distance between the edge of the first surface of a second spacer 32 and the edge of the black matrix region in the sub-pixel region where the second spacer is located may ensure the display effect of the display device.

In an exemplary embodiment, a minimum distance between an edge of a first surface of any sub-spacer in the third spacer 33 and an edge of a black matrix region in a sub-pixel region where the sub-spacer is located may be greater than 10 microns.

In an exemplary embodiment, as shown in FIG. 8, a connection part 332 has a width equal to a difference between a first width W1 and a sum of a second width W2 and a third width W3.

The first width W1 is a distance between the opening region and an edge of the black matrix region, the second width W2 is a distance between a first side of the connection part and the opening region, and the third width W3 is a distance between a second side of the connection part and the black matrix region.

In an exemplary embodiment, all spacers in the display device may be first spacers. At this time, a sum of the areas of first surfaces of all first spacers in a unit area is larger than a first threshold area. The unit area is 1 square millimeter, and the first threshold area refers to the minimum value of the sum of the areas of the first surfaces of all the first spacers in the unit area required by the display device in order to ensure the resistance to pressure of the display device.

In an exemplary embodiment, the first threshold areas corresponding to different display devices are different. For example, for a tablet display device, due to frequent pressing, the required resistance to pressure would be high, and the first threshold area may be about 430 square microns to 450 square microns, for example, 440 square microns. For other display devices, the first threshold area may be about 90 square microns to 110 square microns, for example, 100 square microns.

In an exemplary embodiment, all spacers in the display device may include a first spacer and a second spacer. At this time, a sum of the areas of first surfaces of all first spacers in a unit area is larger than a first threshold area, and the sum of the areas of first surfaces of all first spacers and first surfaces of all second spacers in a unit area is larger than a second threshold area. The unit area is 1 square millimeter, and the second threshold area refers to a minimum value of the sum of the areas of the first surfaces of all spacers in the unit area required by the display device in order to ensure the resistance to pressure of the display device.

In an exemplary embodiment, the second threshold area may be about 24,000 square microns to 26,000 square microns, for example, the second threshold area may be 25,000 square microns.

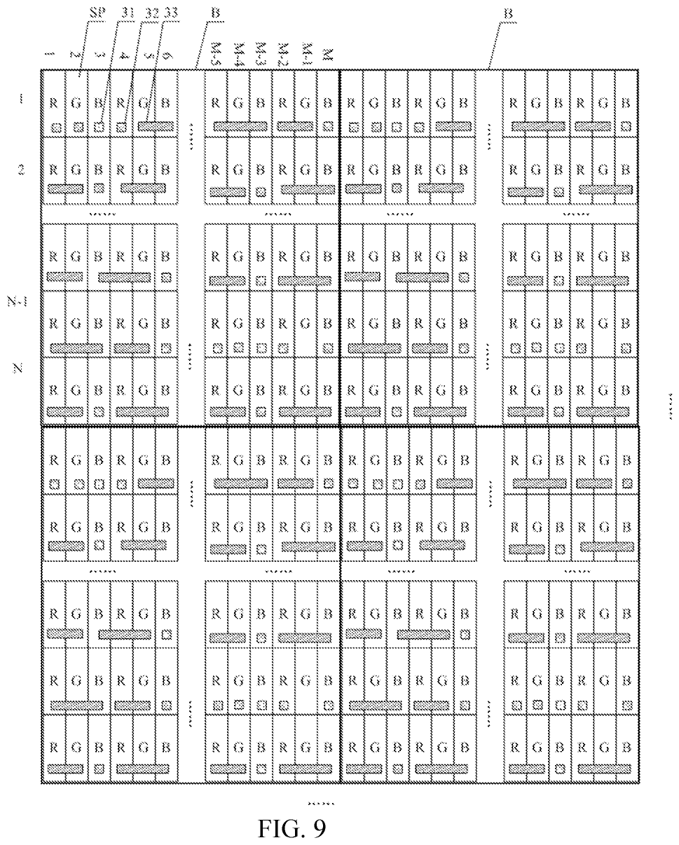

FIG. 9 is a schematic diagram of structure of a display device according to an exemplary embodiment. As shown in FIG. 9, a display device provided by an exemplary embodiment may be divided into a plurality of pixel blocks arranged periodically, and each pixel block includes (M*N) sub-pixel regions. A first spacer 31, a second spacer 32 and a third spacer 33 are disposed in each pixel block.

In an exemplary embodiment, a pixel block may have a length about 2 to 3 microns, and the length of the pixel block may be determined according to the resistance to pressure of the display device.

In an exemplary embodiment, the pixel block may have a width about 2 to 3 microns, and the width of the pixel block may be determined according to the compression to pressure of the display device.

In an exemplary embodiment, both M and N are positive integers greater than or equal to 2, and M and N may be determined according to the resistance to pressure of the display device.

In an exemplary embodiment, M may or may not be equal to N.

In an exemplary embodiment, the first spacer, the second spacer and the third spacer in each pixel block are evenly arranged in a same way, which may ensure the uniformity of the resistance to pressure of the display device.

In an exemplary embodiment, in each pixel block, a sum of the areas of first surfaces of all first spacers in a unit area is larger than a first threshold area, and the sum of the areas of first surfaces of all first spacers, first surfaces of all second spacers, and first surfaces of all third spacers in a unit area is larger than a second threshold area, wherein, the unit area is 1 square millimeter.

In an exemplary embodiment, as shown in FIG. 9, each first spacer may be located in one sub-pixel region, and each second spacer may be located in one sub-pixel region.

In an exemplary embodiment, in each pixel block, a second spacer 32 is disposed in a sub-pixel region adjacent to a sub-pixel region where the first spacer 31 is located, which may ensure evenly distribution of the resistance to pressure around the first spacer 31 and improve the uniformity of the resistance to pressure of the display device The sub-pixel region adjacent to the sub-pixel region where a first spacer 31 is located refers to a sub-pixel region that is located above, below, to the left, or to the right of the sub-pixel region where the first spacer 31 is located.

In an exemplary embodiment, a blank sub-pixel region is spaced from the sub-pixel region where the first spacer is located by one or two sub-pixel regions . The blank sub-pixel region refers to a sub-pixel region where a first spacer, a second spacer or a third spacer is not disposed. The disposition of the blank sub-pixel region may facilitate accurate monitoring of engineering data of the first spacer. When the engineering data of the first spacer does not meet the requirements, the manufacturing parameters of the first spacer are adjusted to achieve batch production, wherein the engineering data may include height and area.

An embodiment of the present disclosure further provides a method for manufacturing a display device, which is used for manufacturing the display device. The method for manufacturing the display device according to the embodiment of the present disclosure includes following acts.

In step S1, forming a display substrate and an opposite substrate which are cell-assembled;

In an exemplary embodiment, the display substrate may be an array substrate, and the opposite substrate may be a color filter substrate; or, the display substrate may be a color filter substrate, and the opposite substrate may be an array substrate, which is not limited by the embodiment of the present disclosure.

In an exemplary embodiment, the array substrate may include: gate lines, data lines, thin film transistors, and pixel electrodes electrically connected to the thin film transistors. The color filter layer may include a black matrix, a color filter layer and a protection layer.

In step S2, forming a first spacer on the display substrate or the opposite substrate.

In an exemplary embodiment, a cross-section of the first spacer may have a shape of rounded polygon.

In an exemplary embodiment, forming the first spacer on the display substrate or the opposite substrate includes: coating a spacer film on the display substrate or the opposite substrate, performing exposure processing on the spacer film through a mask, and developing the spacer film on which exposure processing is performed to form the first spacer.

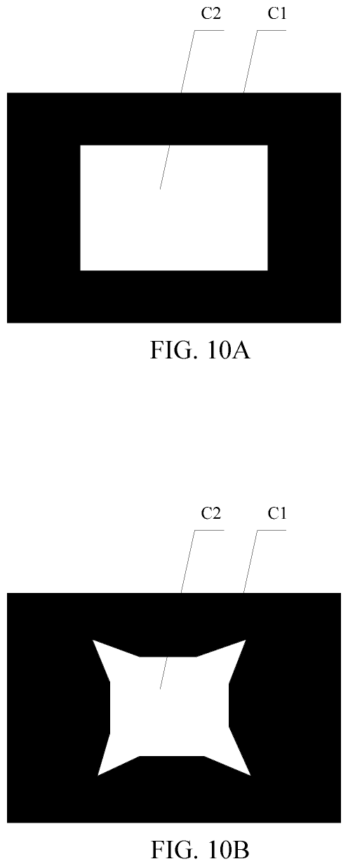

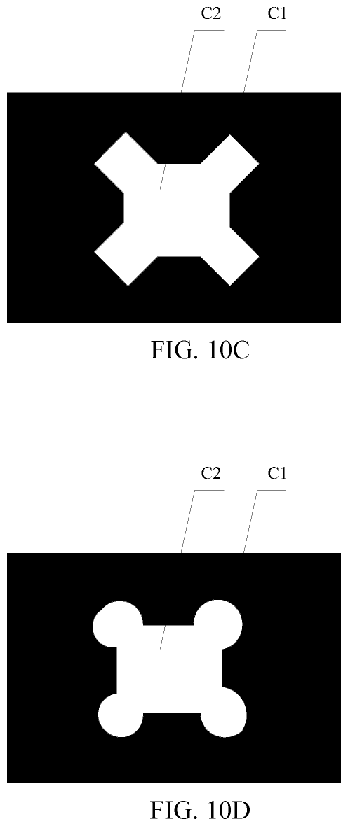

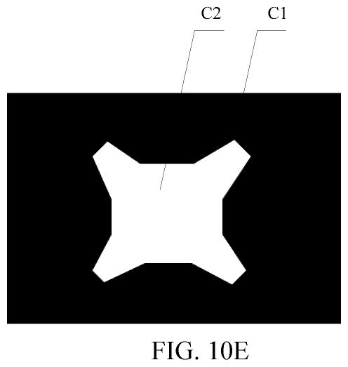

FIG. 10A is a first top view of a mask according to an exemplary embodiment. FIG. 10B is a second top view of a mask according to an exemplary embodiment. FIG. 10C is a third top view of a mask according to an exemplary embodiment. FIG. 10D is a fourth top view of a mask according to an exemplary embodiment. As shown in FIG. 10A to FIG. 10D, a mask includes a non-light transmittance region C1 and a light transmittance region C2.

In an exemplary embodiment, performing exposure processing on a spacer film through the mask may include: performing exposure processing on the spacer film through the light transmittance region of the mask.

In an exemplary embodiment, the light transmittance region may be polygonal, and a plurality of corners of the light transmittance region are provided with exposure compensation patterns. FIG. 10B to FIG. 10E illustrate an example in which a plurality of corners of the light transmittance region C2 are provided with exposure compensation patterns. FIG. 1 illustrates an example in which the light transmittance region C2 is polygonal. The compensation pattern may be a zigzag pattern or a circular arc, which is not limited by the present disclosure.

In an exemplary embodiment, performing exposure processing on the spacer film through the mask includes: performing exposure processing on the spacer film through the light transmittance region of the mask, and performing exposure compensation on the spacer film through the plurality of corners of the light transmittance region of the transparent mask.

In an exemplary embodiment, an exposure compensation mode may be adjusted according to corresponding materials, equipment or process conditions.

In an exemplary embodiment, a spacer formed by exposure compensation processing has an effective compensation effect for a spacer with smaller size.

The display device is the display device according to any one of the previous embodiments, and they are similar in the realization principle and effect, which will not be further described here.

In an exemplary embodiment, a spacer film may be a photoresist film.

In an exemplary embodiment, an exposure machine is used to perform exposure processing on the spacer film through the mask.

In an exemplary embodiment, forming the first spacer on the display substrate or the opposite substrate may include: forming a first spacer and a second spacer, or a first spacer, a second spacer and a third spacer on the display substrate or the opposite substrate.

In an exemplary embodiment, the light transmittance region may be a rectangle.

In an exemplary embodiment, the size and shape of the formed first spacer may be adjusted in combination with different exposure machines and exposure conditions, which can increase the supporting area of the first spacer and improve the strength of resistance to pressure of the display device on the premise of little influence on the aperture ratio of the display device.

The drawings in the present disclosure only involve the structures included in the embodiments of the present disclosure, and other structures may refer to common designs.

For the sake of clarity, the thickness and size of layers or microstructures are exaggerated in the drawings used to describe the embodiments of the present disclosure. It may be understood that when an element such as a layer, film, region or substrate is referred to as being “on” or “under” another element, the element may be “directly” “on” or “under” another element, or there may be a middleware.

Although the embodiments disclosed in the present disclosure are as described above, the described contents are only the embodiments for facilitating understanding of the present disclosure, which are not intended to limit the present disclosure. Those of ordinary skilled in the art to which the present disclosure pertains may make any modifications and variations in the form and details of implementation without departing from the spirit and the scope of the present disclosure. Nevertheless, the scope of patent protection of the present disclosure shall still be determined by the scope defined by the appended claims.

What we claim is:

1. A display device, comprising:
a display substrate and an opposite substrate which are oppositely disposed and cell-assembled, and a first spacer disposed between the display substrate and the opposite substrate,
wherein a cross-section of the first spacer has a shape of rounded polygon.

2. The display device according to claim 1, wherein the cross-section of the first spacer has a shape of rounded rectangle.

3. The display device according to claim 2, further comprising a second spacer disposed between the display substrate and the opposite substrate; and
a cross-section of the second spacer has a same shape as the cross-section of the first spacer, and the first spacer has a height greater than a height of the second spacer.

4. The display device according to claim 3, further comprising: a plurality of sub-pixel regions arranged in an array and a third spacer disposed between the display substrate and the opposite substrate,
the third spacer is located in the plurality of sub-pixel regions.

5. The display device according to claim 4, wherein the third spacer is located in two or three sub-pixel regions.

6. The display device according to claim 4, wherein the third spacer comprises M sub-spacers and (M-1) connection parts; and
each sub-spacer is located in one of the sub-pixel regions, and two adjacent sub-spacers are connected by one of the connection parts, the sub-spacer has a height equal to the height of the second spacer, and the connection part has a height equal to the height of the sub-spacer.

7. The display device according to claim 6, wherein a cross-section of the sub-spacer has a shape of circle, ellipse or rounded polygon, and a cross-section of the connection part has a shape of strip.

8. The display device according to claim 6, wherein a surface of the connection part close to the display substrate has a width smaller than a width of a surface of the sub-spacer close to the display substrate.

9. The display device according to claim 8, wherein the surface of the connection part close to the display substrate has a width greater than or equal to 6 microns.

10. The display device according to claim 4, wherein the display substrate or the opposite substrate comprises a black matrix layer provided with a plurality of openings, and each sub-pixel region comprises a black matrix region and an opening region, and the black matrix region surrounds the opening region;
each of the first spacer, the second spacer and the third spacer comprises: a first surface close to the display substrate and a second surface close to the opposite substrate, wherein the first surface has an area larger than an area of the second surface; and
a minimum distance between an edge of the first surface of the first spacer and an edge of a black matrix region in a sub-pixel region where the first spacer is located is greater than 12 microns.

11. The display device according to claim 10, wherein a minimum distance between an edge of the first surface of the second spacer and an edge of a black matrix region in a sub-pixel region where the second spacer is located is greater than 10 microns.

12. The display device according to claim 10, wherein a minimum distance between an edge of a first surface of any sub-spacer in the third spacer and an edge of a black matrix region in a sub-pixel region where the sub-spacer is located is greater than 10 microns.

13. The display device according to claim 1, wherein the first spacer comprises a first surface close to the display substrate and a second surface close to the opposite substrate, wherein the first surface has an area larger than an area of the second surface; and
a sum of the areas of first surfaces of all first spacers in a unit area is larger than a first threshold area, wherein the unit area is 1 square millimeter.

14. The display device according to claim 3, wherein each of the first spacer and the second spacer comprises a first surface close to the display substrate and a second surface close to the opposite substrate, wherein the first surface has an area larger than an area of the second surface; and
a sum of the areas of first surfaces of all first spacers in a unit area is larger than a first threshold area, and a sum of the areas of first surfaces of all first spacers and first surfaces of all second spacers in a unit area is larger than a second threshold area, wherein the unit area is 1 square millimeter.

15. The display device according to claim 4, wherein the display device is divided into a plurality of pixel blocks arranged periodically, and each pixel block comprises M*N sub-pixel regions; and each pixel block is provided with the first spacer, the second spacer and the third spacer;
the pixel block has a length of 2 microns to 3 microns, and the pixel block has a width of 2 microns to 3 microns; and
the first spacer, the second spacer and the third spacer in each pixel block are arranged evenly and in a same way.

16. The display device according to claim 15, wherein each of the first spacer, the second spacer and the third spacer comprises: a first surface close to the display substrate and a second surface close to the opposite substrate, wherein the first surface has an area larger than an area of the second surface; and
in each pixel block, a sum of the areas of first surfaces of all first spacers in a unit area is larger than a first threshold area, and a sum of the areas of first surfaces of all first spacers, first surfaces of all second spacers, and first surfaces of all third spacers in a unit area is larger than a second threshold area, wherein the unit area is 1 square millimeter.

17. The display device according to claim 16, wherein each first spacer is located in a sub-pixel region, and each second spacer is located in a sub-pixel region; and
in each pixel block, a sub-pixel region adjacent to the sub-pixel region where the first spacer is located is provided with the second spacer, and a blank sub-pixel region is spaced from the sub-pixel region where the first spacer is located by one or two sub-pixel regions.

18. A method for manufacturing a display device, for manufacturing the display device according to claim 1, comprising:
forming a display substrate and an opposite substrate which are cell-assembled; and
forming a first spacer on the display substrate or the opposite substrate, wherein a cross-section of the first spacer has a shape of rounded polygon,
wherein forming the first spacer on the display substrate or the opposite substrate comprises: coating a spacer film on the display substrate or the opposite substrate, performing exposure processing on the spacer film through a mask, and developing the spacer film on which exposure processing is performed to form the first spacer,
the mask comprises a non-light transmittance region and a light transmittance region; the light transmittance region is polygonal, and a plurality of corners of the light transmittance region are provided with exposure compensation patterns; and
performing exposure processing on the spacer film through the mask comprises: performing exposure processing on the spacer film through the light transmittance region of the mask, and performing exposure compensation on the spacer film through the plurality of corners of the light transmittance region of the mask.

19. The method according to claim 18, wherein, forming the first spacer on the display substrate or the opposite substrate comprises:
forming the first spacer and a second spacer, or forming the first spacer, the second spacer and a third spacer on the display substrate or the opposite substrate.

20. The method according to claim 18, wherein, the light transmittance region is rectangular.
